(19) United States
(12) Patent Application Publication
(10) Pub. No.: US 2011/0272788 A1
(43) Pub. Date: Nov. 10, 2011

(54) Computer system wafer integrating different dies in stacked master-slave structures

(75) Inventors: Kyu-hyoun Kim, Yorktown, NY (US); Paul Coteus, Yorktown, NY (US)

(73) Assignee: International Business Machines Corporation, Armonk, NY (US)

(21) Appl. No.: 12/777,177

(22) Filed: May 10, 2010

(51) Int. Cl. H01L 29/06; H01L 21/00

(52) U.S. Cl. 257/618; 438/113; 257/E29.026; 257/E21.001

(57) ABSTRACT

A stacked 3D integrated circuit structure is manufactured with a common image design for dies which allows diced master dies to cut from the common wafer and diced slave dies cut to be cut from a wafer which has the common image design. In an embodiment is stacked to form a wafer-to-wafer 3D stack before dicing. Master and slave elements which are used for only one kind of separated individual integrated circuit dies which are located along die edges and at die centers before dicing separation of individual integrated circuit chips. A master wafer is shifted ½ way across a die to make cutting along a kerf line effective to provide both master and slave dies. Multiple slaves can be stacked and coupled to a master die which acts as a bus master when attached to a bus to which only the master die is directly connected. The use of a common wafer design minimizes cost of manufacture of chips destined to be stacked as 3D integrated circuits.

### TRADEMARKS

IBM® is a registered trademark of International Business Machines Corporation, Armonk, N.Y., U.S.A. Other names used herein may be registered trademarks, trademarks or product names of International Business Machines Corporation or other companies.

### BACKGROUND OF THE INVENTION

1. Field of the Invention

This invention relates to a computer processing system, and particularly to integrating different dies formed from a wafer which are used as system elements in stacked master-slave structures.

2. Description of Background

Before our invention U.S. Pat. No. 5,655,113 and its divisional US patents described a computer processing system using a bus system for circuit module architecture system elements to enable a number of memory modules to be coupled in parallel to a master I/O module through a single directional asymmetrical signal swing bus. Semiconductor Equipment and Materials International (SEMI®) a leading organization for standards in the industry, recently in July, 2009, after our invention, has announced the release of a white paper on the rapid progress of 3D IC integration technology, including Through Silicon Via (TSV) developments, with a white paper intended to provide chip makers, equipment and materials suppliers, industry technologists, investors and analysts with a snapshot guide of the rapidly developing technology which was entitled, 3D Integration: An Industry Progress Report. TSV has been one of the most rapidly developing technologies in the semiconductor industry and the SEMI′ white paper guide proposes that it promises a fundamental shift for the continued role of Moore's Law and current multi-chip integration and packaging approaches described in U.S. Pat. No. 5,655,113 and others which use current integration schemes such as wire bond and flip chip. The SEMI white paper guide suggests the next-generation of 3D integration will incorporate through-silicon via (TSV) technology as the primary method of interconnect. The drivers for the widespread adoption of TSVs are increased performance, reduced form factor, and cost reduction. Additionally the paper advises that achieving true heterogeneous integration at the local level will require a high-density TSV solution and development efforts believed to be rapidly occurring by numerous organizations around the world. The paper recognizes critical development areas in TSV formation and subsequent stacking processes which include those that address insulator/barrier/seed, etching/plating, thin wafer handling for permanent and temporary bond/debond process, and pick-and-place stacking. In addition, the paper identifies and explores limitations to market adoption of 3D integration using TSVs, including lack of design tools, thermal management issues, test solutions, and supply chain issues. The report concludes that the successful achievement of all of these technologies relies on collaboration and participation across the supply chain. The paper calls for more communication and information sharing between the design, test, and manufacturing communities to accelerate the march towards market adoption of TSVs to promote development of 3D integration. However, even though the SEMI paper was published after our own invention, this white paper does recognize many issues with TSV development. For instance, using Through Silicon Vias (TSVs) can be an efficient way to reduce the I/O loading of a total stacked chip for 3D integration, but as the SEMI paper says there are problems which lead to higher manufacturing costs, such as, stacking chips from two separate dies—master and slave—which are manufactured from two different kinds of wafers leads to higher manufacturing cost.

### SUMMARY OF THE INVENTION

This invention provides an efficient way to get both master and slave chip dies from a single wafer without increasing die size from what is minimally required. We provide a single image wafer which is diced to provide master and slave chip dies. In this invention, those master or slave elements which are used only for only one kind of die are located at a die edge and/or die center as shown in the accompanying drawings.

In accordance with our invention now only a single wafer design having master and slave elements for each of master and slave integrated circuit dies can be made and from the same wafer design. 3D integrated circuit stacks can be fabricated to enable a master integrated circuit die having an I/0 circuit connected to a master bus which acts as a buffer for any slave dies of a 3D integrated circuit structure to be made from a single wafer design. When slave dies made from the single wafer design are stacked on the a master integrated circuit having I/O circuit drivers by which they are coupled to the master bus only through the master integrated circuit die which controls access to a shared data bus to isolate a master bus channel from activity within slave dies which are connected by Through Silicon Vias (TSVs) to the master die as part of the stacked 3D integrated circuit structure to provide an efficient way to reduce the I/O loading of the total stacked chip. This 3D integrated structure can now be efficiently made from only one single wafer design which has chip master and slave elements which are used only for only one kind of die are located at a die edge and/or die center which determine the chip function. This reduces manufacturing cost.

The method, system and computer product corresponding to the above-summarized distinction and those shown in the drawings are also described and claimed herein.

Additional features and advantages are realized through the techniques of the present invention. Other embodiments and aspects of the invention are described in detail herein and are considered a part of the claimed invention. For a better understanding of the invention with advantages and features, refer to the description and to the drawings.

As a result of the summarized invention, technically we have achieved a solution which provides an efficient way to get both master and slave dies from a single wafer without increasing die size from what is minimally required.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates stacked 3D chips bump bonded to a board/asic substrate.

FIG. 2 illustrates a segment of the common wafer for the stacked chips of a 3D stack in accordance with the invention.

FIG. 3 shows diced master dies cut from the common wafer a segment of which is illustrated by FIG. 2.

FIG. 4 shows diced slave dies cut from the common wafer a segment of which is illustrated by FIG. 2.

FIG. 5 shows a full wafer from which the segment of FIG. 2 is illustrated which is stacked to form a wafer-to-wafer 3D stack before dicing.

FIG. 6 illustrates a wafer-to-wafer 3D stack with the areas from which master and slave segments are diced.

FIG. 7 shows a master-slave stacked die after dicing.

The detailed description explains the preferred embodiments of the invention, together with advantages and features, by way of example with reference to the drawings.

### DETAILED DESCRIPTION OF THE INVENTION

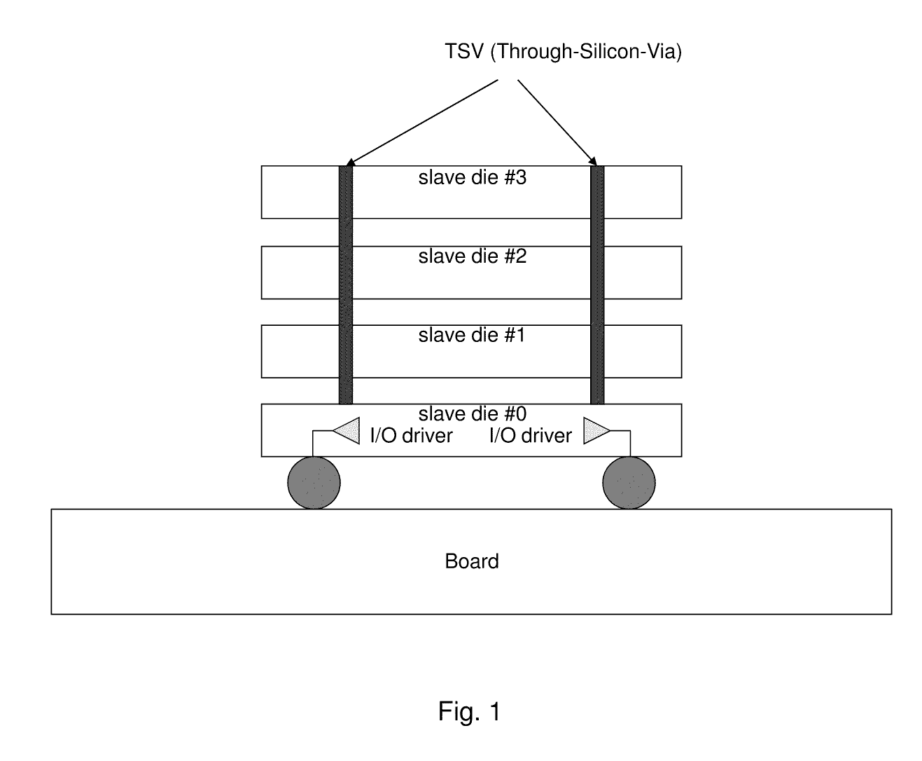

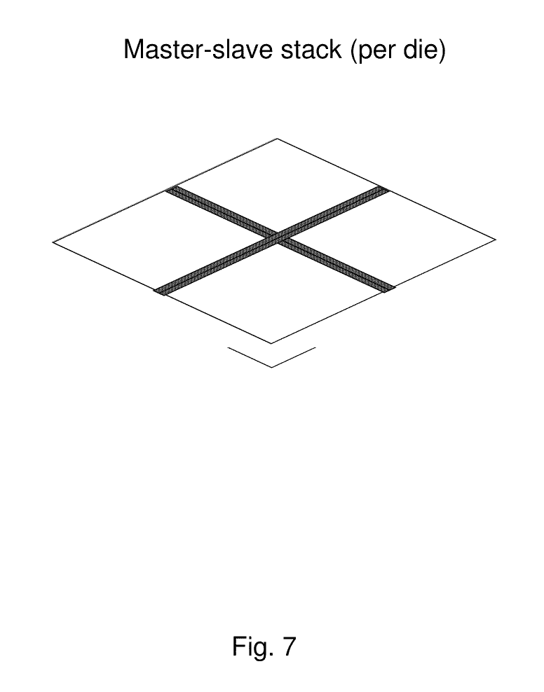

Turning now to the drawings in greater detail, it will be appreciated that as shown in FIG. 1, a 3D stacked master-slave TSV structure which can be provided where the bottom die interfaces to the outside of the component and upper dies communicate only with the master die using the I/O drivers on master slave die #0 to communicate through the bump connectors to the bump connected board/asic substrate on which the 3D stack structure is mounted. A preferred stack is illustrated in FIG. 7. Just as is shown in FIG. 1, after separation individual circuit dies are stacked as a 3D chip stack bump bonded board/asic substrate carrying said master bus, each die of said 3D chip stack being separated from a single wafer with a common wafer image of integrated circuits which have die circuit connection elements useful as master and as slave elements in dies separable from one or more wafers having said common wafer image.

Here the TSV structure has the bottom slave die #0 acting as the master slave die to connect to other elements (not specifically shown) or other 3D stacked structures mounted on the board. The stacked slave dies #1, 2, 3 communicate to the other circuit elements on the board/asic substrate only through the Through Silicon Vias connections to the master die #0 and through TSVs (Through Silicon Vias) to that die as well as to other stacked slave elements of the 3D structure to provide an efficient way to reduce the I/O loading of the total stacked chip. As we have said, this invention provides an efficient way to get both master and slave dies from a single wafer without increasing die size from what is minimally required. In this invention, those elements which are used only for only one kind of die are located at a die edge and/or die center as shown in the accompanying drawings.

This TSV structure overcomes the need to have two separate dies—master #0 and slave #1, 2, 3 manufactured from two different kinds of wafers which leads to a higher manufacturing cost were it not for the improvements of the preferred embodiment illustrated herein. Alternative to our preferred embodiment, we suggest, is a manufacture which could both separate master and slave dies from a single wafer where each die includes both TSV connection paths (as shown in dies #1, #2, #3) and I/O drivers (as shown on die #0) on the dies #0, #1, #2, #3 even though a TSV structure is not required for master dies and I/O circuits are not required for slave dies. This alternative does mean a larger die size and higher cost again.

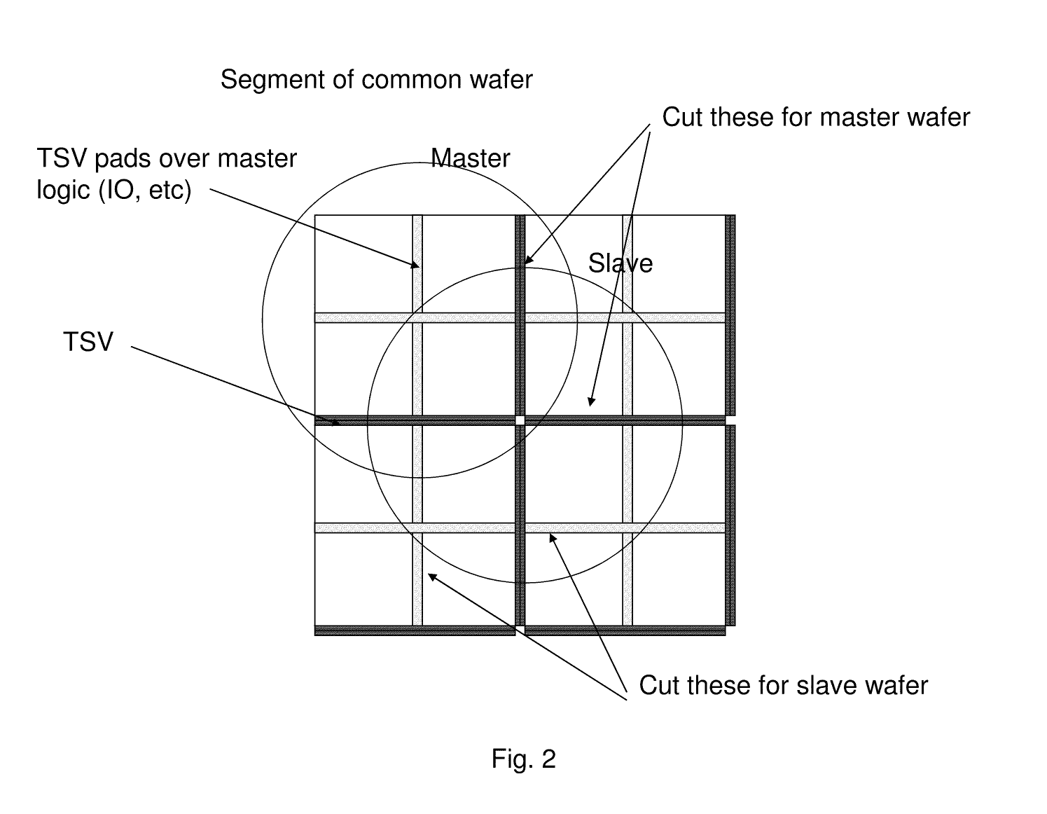

But, briefly, as we have said, the preferred embodiment of this invention provides an efficient way to get both master and slave dies from a single wafer with diced wafer dies used as either master slave dies or slave dies as shown by the segment of a wafer's common die floorplan illustrated in more detail by FIG. 2 without increasing die size from what is minimally required. The wafer's dies have elements deposited on the wafer with a common floorplan which contains in possible die areas connection elements useful in a master die structure or in a slave die structure, even though the connection elements need not be used in one or the structures of dies extracted from the common floorplan of the wafer. In our example, the connections elements include I/O circuit elements and TSV elements. The I/O circuit elements need not be used by a slave die, and the TSV elements need not be used by a master die. Both, however, are provided for the image of a common die floorplan to enable master or slave dies to be extracted from the wafer by the method described herein. Separating individual circuit dies locates master elements at die centers of a master die having logic master elements for connection to a master bus, and locates through silicon vias (TSV) slave elements of a die cut from a like wafer with the same wafer image of integrated circuits used as a slave die so that said slave die is connected to a die having logic master elements for coupling to a master bus in a stacked circuit configuration.

Generally, in a master slave structure, the master die is used to communicate to elements coupled to it via bus on a base substrate or circuit board, while a slave die is used to couple logic devices contained within its die to other slave dies or to the master die, but not directly to a master bus to which the master bus is connected. As an example, one can with the dies provided by our invention in a stacked 3D integrated circuit structure which has a master die with an I/0 to a master bus which acts as a buffer for a plurality of slave dies providing a memory bank which are coupled to the master bus only through the master die which controls access to a shared data bus. The master die structure isolates the channel from activity within the slave dies which are connected by TSVs to the master die as well as to other stacked slave elements of the 3D structure to provide an efficient way to reduce the I/O loading of the total stacked chip. This example would, by the 3D integration described, provide better memory access than available via a group of dies having the same memory capacity but each coupled to a master bus. Dies using the preferred master slave structure are diced from integrated 3D stacks of the common master slave wafer integrating different dies which are then integrated in 3D stacked master-slave structures. In accordance with this invention, those elements which are used only for only one kind of die are located in a region along a die edge and/or die center of the common floorplan as shown in FIG. 2. Thus, in manufacturing, creating a single wafer with a wafer image of integrated circuits which have die circuit connection elements useful as master and as slave elements in dies separable from said single wafer, and separating individual integrated circuit dies from the single wafer as chip dies having elements for interconnection of the separated individual integrated circuit dies with master and slave elements which are used for only one kind of separated individual integrated circuit dies which are located along die edges and at die centers before dicing separation of individual integrated circuit chips, is used to have the location of master and slave elements determine whether a separated individual integrated circuit chip is used as a master or a slave element in a stacked circuit configuration. In a preferred example shown in FIG. 7, the determining I/O circuit elements and Through Silicon Via elements cross in the center of the die after dicing.

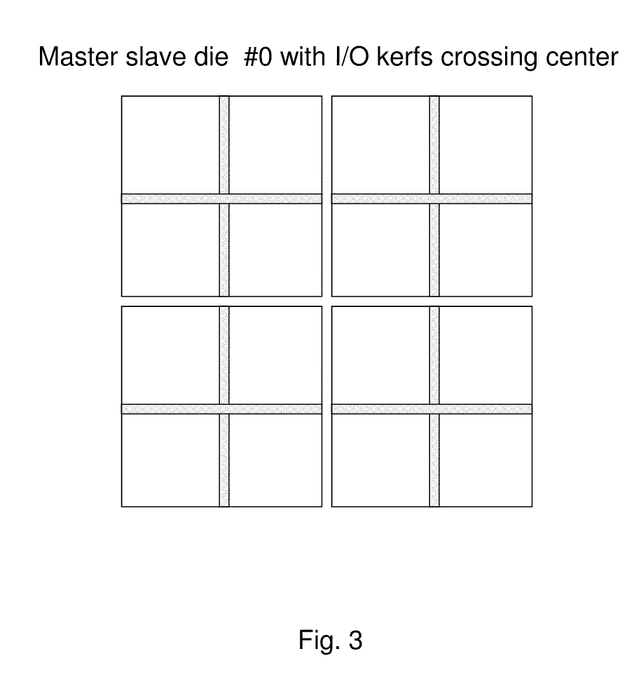

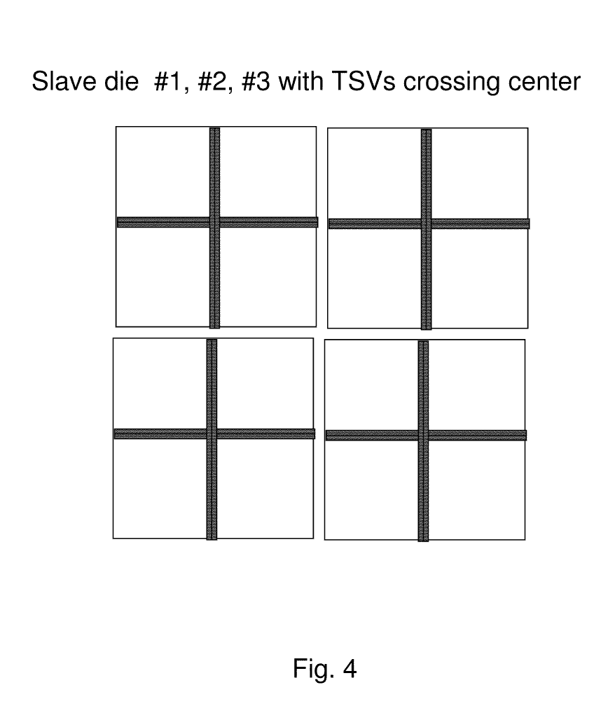

For example, as referenced to a master die #0, I/O circuits will be located at die center with ‘cross’ type of kerf floorplan, and TSVs will be located long the die edge of the kerf floorplan. As referenced to slave dies #1, 2, 3, I/O circuits will be located along the die edge area and TSVs will be located at the die center with ‘cross’ type of common floorplan, So, to get master dies from the wafer, we have only to scribe (cut) dies along TSV region as illustrated in FIG. 3. To get slave dies from the wafer, we have only to scribe dies with a different cutting coordinates which are shifted by ½ die area for both X and Y-axis, which is for scribing across the I/O circuit region illustrated in FIG. 4.

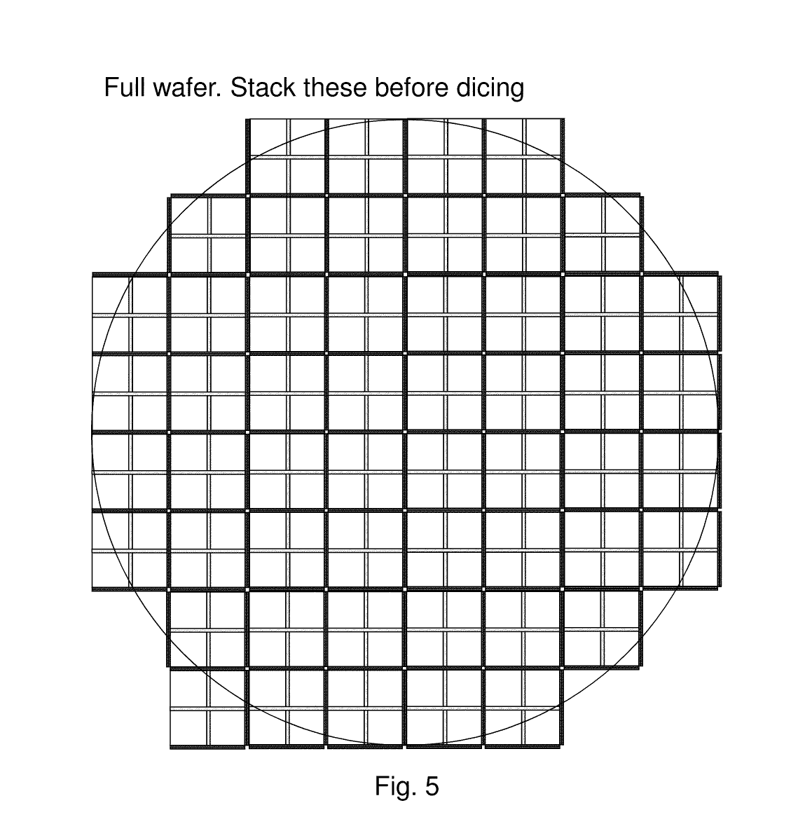

In this example, as referenced to a master die, I/O circuits will be located along a kerf crossing at a die center having a ‘cross’ type of floor-plan in a master slave area, and TSV elements will be located along the die edge in order to be able to be cut along the kerfs for the TSVs in such an area destined to be a master slave die as illustrated in FIG. 3. A ‘cross” type floor-plan generally has an orthogonal arrangement of kerfs which look like they mark a checkerboard pattern from above, or otherwise demarks a group of die areas in a pattern suitable for cutting, as shown in FIG. 5. With reference to a slave die, I/O circuits will be located along the die edge area of those circuits intended to be slave dies and the slave die's TSV elements will be located with kerf crossings at the die center of the ‘cross’ type of floor-plan with orthogonally crossing kerf areas so that a slave die can be made as shown in FIG. 4. So the upper left quadrant of the illustrated single wafer segment has TSV pads over the master logic (I/O drivers and other elements used by the master chip for communication) while the slave die areas has the TSV connection made along the edge of the dice cut kerf of the master slave die. Thus to make a master slave die cut, the kerf cut through is the kerf having the TSVs along the edge of the die. To make a slave die, the kerf cut through is the kerf having the I/O circuits. After separating dies from wafers having a common single image, a plurality of slave dies are stacked in a 3D circuit stack with interconnecting Through Silicon Vias crossing the center being used to interconnect the plurality of slave dies and to connect the plurality of stacked slave dies placed on a master die to a master die as an integrated 3D circuit stack, and connecting the master die to a master bus on a board/asic substrate as the only die of the integrated circuit stack coupled externally of the integrated circuit stack.

These cuts are made by a laser cutter or by a saw blade in accordance with the method of cutting chosen. Generally, we prefer to use a laser ablation cutter for thinner stacked wafers while using a saw blade for thick wafers. This allows master dies and slave dies to be cut out of a common master slave wafer as illustrated in FIG. 5.

As illustrated in FIG. 5, the master dies formed as master slave dies will be those cut along the TSV edges (shown more heavily lined), while the slave dies will the those cut out through the center of the I/O circuit regions of dies cut from a wafer which after cutting are aligned along the edge of the slave dies. In FIG. 2 the kerfs for the slave dies are shown crossing in the center as more lightly lined kerfs, while those which have the TSV connections are made along the edge of the dice cut as shown as having the darker kerf TSV crossing in the center of the die to allow separation of slave dies by cutting through the I/O circuit's kerf.

Accordingly, to get master slave dies from the wafer, the manufacture of this invention only has to scribe (cut) dies along TSV edge region cut through the TSV slave kerf to obtain the master die cut resulting in the crossing I/O circuit region pads for master logic crossing in the center if the die as illustrated by FIG. 3 which functions as a master die illustrated in FIG. 1 as the master slave die #0. To obtain those slave dies #1, #2, and #3 from the wafer as illustrated by FIG. 4, the manufacture of this embodiment has only to scribe dies with a different cutting coordinates which shift by ½ the distance across the die area for both the X and Y-axis, which is a cut through the I/O circuit region pad area to locate the crossing of TSVs for the slave die kerf pattern cut resulting the die cut shown in FIG. 4. Thus the kerf pattern used for the master wafer has alternating orthogonal crossing kerfs across a wafer, with each alternation changing first from a master connection with TSV pads on the edge of the chip area to kerfs where the I/O circuits' chip region area is cut so that cut die will be a slave die. A shift ½ way across the die provides a second interconnection TSV region crossing kerf pattern which has I/O circuit regions which when cut allows the chip cut to be a slave die. The kerf pattern can be obtained from a file or generated during the wafer design with kerf design data corresponding to the chip data to obtain the kerf design. A method for obtaining a kerf pattern can be that described in U.S. Pat. No. 7,275,234 issued to IBM, which is fully incorporated herein for reference.

FIG. 2 illustrates a segment of a full wafer showing the possibility of having the illustrated master slave die and the three slave dies formed thereon before dicing. This wafer has operational circuit elements from on the wafer in addition to the masked kerf regions shown. These operational circuits are interconnected to the I/O via the TSVs as well as to each other on the same wafer. Slave circuits can typically include memory elements, or redundant processor elements. A master slave die will typically have I/O drivers, A/D converters, clock, sensors and glue logic. Diced segments are illustrated by FIGS. 3 and 4. FIG. 5 shows an example of a full wafer layout of the dies illustrating how master and slave elements are laid out using a common floorplan with both I/O circuit elements and TSV elements being laid out on a common floorplan die area with I/O circuits kerf region located along the die edge area of a slave die and TSV pads for master logic elements will be located at the die center of the ‘cross’ type of floor-plan for the master slave dies. In this example all of the common floorplan die areas can be part of either a master or a slave die when diced. I/O kerfs and slave kerfs are located for awafer image with an orthogonal pattern for each kerf pattern crossing with a shift ½ way across a die which would be separated from the wafer so as to provide an I/O interconnection pattern with one cut which when cut allows a chip cut to be a master die and a second interconnection TSV region crossing kerf pattern with a second cut shifted ½ way across the die which when cut allows the chip cut to be a slave die.

The full wafer illustrated by FIG. 5 in accordance with one alternative embodiment of the invention will be stacked before dicing. Automatic wafer stacking machines are available commercially and can be used for this purpose. Alignment registration for 3D stacking is achieved by these machines and wafer bonding of wafers to wafer is made. There are three major approaches for wafer bonding for wafer-level 3-D integration. Both direct oxide bonding and dielectric adhesive bonding use a via-second process, while metal-to-metal bonding uses a via-first process flow. Typically dielectric adhesive bonding is the preferred choice. By repeating the process flow for a pair of wafers which are bonded, before dicing additional wafers can be aligned, bonded, thinned and inter-wafer interconnected. This approach does not require handling wafers, as thinned silicon is not transferred. Many applications would require two- or three- or four-wafer stacks as illustrated in FIG. 1.

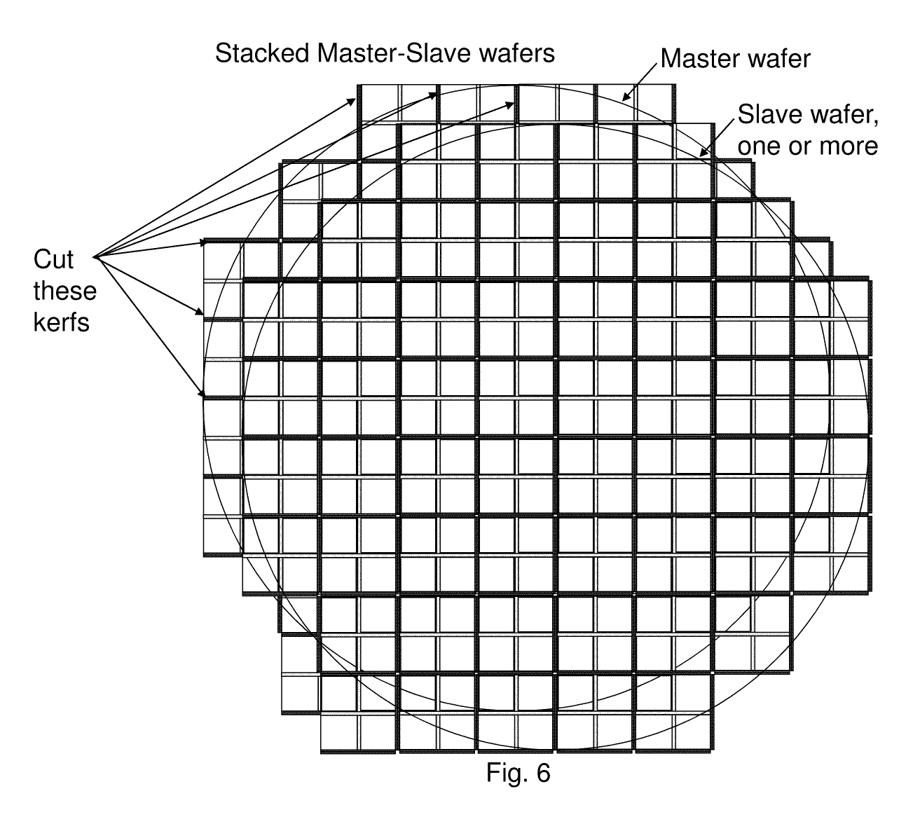

FIG. 6 illustrates the stacked master-slave wafers of FIG. 5 before dicing. Note that there is an offset. Kerfs of the mask are made corresponding to the ‘cross’ type master slave die for master dicing through the TSV interconnection kerfs with TSVs on the edge of the die leaving the master logic I/O kerf in the center of the die, and master logic kerfs are also made for the slave dies along the TSV pads over the master logic which are cut for the diced slave die leaving the TSV interconnection kerfs crossing in the center of the diced slave die interconnection vias. Just as shown in the segment shown in FIG. 2, in FIG. 6 for a master slave #0 die, I/O circuits will be located at die center with ‘cross’ type of floor-plan, and TSV interconnections will be cut along the die edge. As referenced to a slave die, I/O circuits will be located along the die edge area which is cut on dicing and TSV interconnections will be located for crossing at the die center with the orthogonal ‘cross’ type of floor-plan. Thus, before the dies are separated from a wafer, a plurality of wafers are stacked and vertically aligned as stacked master slave wafers, the wafers being aligned with one of the vertically aligned wafers being shifted to align with a kerf pattern crossing shifted ½ way across the die pattern which will be cut, such that a cut along a kerf line will separate master dies from one of the vertically aligned wafers and slave dies adjacent to the master dies by cutting through aligned I/O kerf patterns of one wafer and TSV kerf patterns of a different wafer of the stacked wafers to provide a resulting stack of vertically aligned chips having aligned I/O interconnection patterns and TSV patterns of respective master die and slave dies.

So, to get master dies from the wafer, kerfs are made to have a scribe (cut) of the dies along TSV interconnection region. To get slave dies from the wafer, kerfs are made to scribe the dies with a different cutting coordinates which shift across ½ the die area for both an X and Y-axis, for the I/O circuit area. So the stack of full wafers before kerfing will be shifted to have the coordinates for a planned final stack die appropriately aligned to connect the TSVs for the planned die. Then a single cut through the selected kerfs will cut through multiple layers to provide aligned integrated 3D stacked circuits with a master slave die for I/O interconnection via master logic to an external substrate and other circuits and one or preferably multiple stacked slave dies connected to each other and via the master slave I/O die for connection to the external substrate's other circuits.

FIG. 7 shows the planned final stack die with a master slave die covered (but seen through the covering wafer segment) by a slave die covering and bonded to the master slave die wafer segment. A single wafer with a wafer image of integrated circuits which have die circuit connection elements useful as master and as slave elements in dies separable from a single wafer provides the elements for the final stack die. I/O kerfs and slave kerfs are located for a wafer image with a orthogonal pattern so that a dicing cut along an I/O kerf will cause I/O drivers to cross in a centered master die after separation and slave kerfs will locate Through Silicon Vias crossing in a centered slave die after separation as shown. Additional slave dies can cover the illustrated set of wafers by repeating the process flow for the pair of wafers which are bonded, before dicing and the additional wafers can be slave dies aligned, bonded, thinned and inter-wafer interconnected before dicing.

While the preferred embodiment to the invention has been described, it will be understood that those skilled in the art, both now and in the future, may make various improvements and enhancements which fall within the scope of the claims which follow. These claims should be construed to maintain the proper protection for the invention first described.

What is claimed is:

1. An integrated circuit chip element for an electronic product, comprising:
a master integrated circuit die cut from a wafer having master logic elements formed thereon and separated by dicing from among master and slave elements which are used for only one kind of individual integrated circuit die to be cut from said wafer and which master and slave elements are located along die edges and at die centers before dicing separation of individual integrated circuit dies from said wafer, the location of said master and slave elements determining that said master integrated circuit die is used as a master die and not as a slave element when a master dicing pattern has cut out the master integrated circuit die from said wafer.

2. The integrated circuit chip element according to claim 1, in combination with a slave integrated circuit die cut from a wafer having through silicon vias (TSVs) slave elements formed thereon and separated by dicing from among master and slave elements which are used for only one kind of individual integrated circuit die to be cut from a wafer which has both master and slave elements are located along die edges and at die centers before dicing separation of individual integrated circuit dies from said wafer, the location of said master and slave elements determining that said slave integrated circuit die is used as a slave die and not as a master die when a dicing pattern has cut out the slave integrated circuit die from said wafer and locates through silicon vias (TSV) slave elements of said slave integrated circuit die for connection of circuits on said slave integrated circuit die to other chip elements.

3. The integrated circuit chip element according to claim 2, wherein after separation individual circuit dies are stacked as a 3D chip stack bonded board/asic substrate carrying a master bus, each die of said 3D chip stack being separated from a wafer with a common wafer image of integrated circuits which have die circuit connection elements useful as master and as slave elements in dies separable from one or more wafers having said common wafer image.

4. The integrated circuit chip element according to claim 2, wherein I/O kerfs and slave kerfs are located on the wafer from which said master integrated circuit die and said slave integrated circuit die have been cut, the I/O kerfs and slave kerfs having an orthogonal pattern so that a dicing cut along an I/O kerf cut pattern causes I/O drivers to cross in a centered master integrated circuit die after separation and slave kerfs will locate Through Silicon Vias crossing in a centered slave integrated circuit die after separation.

5. The integrated circuit chip element according to claim 4, wherein said I/O kerfs and slave kerfs are located with an orthogonal pattern for each kerf pattern crossing with a shift ½ way across a die which has been be separated from the wafer so as to provide an I/O interconnection pattern for a master integrated circuit die and a second interconnection TSV region crossing kerf pattern, said kerf patterns establishing the function of an integrated circuit die cut from a wafer by being shifted ½ way across an integrated circuit die.

6. The integrated circuit chip element according to claim 5 wherein the master and one or more slave integrated circuit dies separated from wafers having a common image are stacked in a 3D circuit stack with interconnecting Through Silicon Vias crossing the center of a die along a kerf pattern which has not been cut is used to interconnect the dies of a 3D circuit stack and to interconnect the slave integrated circuit dies to a master integrated circuit die element of an integrated 3D circuit stack structure, and wherein I/O logic connecting said master die to a master bus on a board/asic substrate as the only die of the integrated circuit stack coupled externally of the integrated circuit stack crosses the center of said master integrated circuit die along a kerf pattern which has not been cut.

7. The integrated circuit chip element according to claim 5 wherein in the process of manufacturing master and slave integrated circuit dies which are cut from a wafer and before said dies are separated from a wafer, a plurality of wafers are stacked and vertically aligned as stacked master slave wafers, said wafers being aligned with one of said vertically aligned wafers being shifted with an aligned kerf pattern crossing shifted ½ way across the die pattern before it is cut, such that a cut along a kerf line will separate master dies from one of said vertically aligned wafers and slave dies adjacent to said master dies by cutting through aligned I/O kerf patterns of one wafer and TSV kerf patterns of a different wafer of said stacked wafers to provide a resulting stack of vertically aligned chips having aligned I/O interconnection patterns and TSV patterns of respective master die and slave dies.

8. A three dimensional circuit stack for an electronic system, comprising:
a base board/asic substrate having a master bus formed thereon for passing signals between elements to which it is coupled in said computer system;
a stacked 3D integrated circuit structures which is bump bonded to said base board/asic substrate, including, in said stacked 3D integrated circuit structure, a master integrated circuit die which is bump connected to said base board/asic substrate and
at least one slave integrated circuit die connected to said master integrated circuit die via through silicon vias for coupling circuits formed on said at least one slave integrated circuit die to other circuits in said computer system,
said coupling to other circuits in said computer system which are external to said master integrated circuit die being made by way of said master integrated circuit die connection to said base board/asic substrate in said stacked 3D integrated circuit structure which has a master integrated circuit die having an I/O circuit connected to said master bus which master integrated circuit die acts as a buffer for any slave dies of said 3D integrated circuit structure which are coupled to the master bus only through the master integrated circuit die which controls access to a shared data bus to isolate a master bus channel from activity within slave dies which are connected by TSVs to the master die as part of said stacked 3D integrated circuit structure to provide an efficient way to reduce the I/O loading of the total stacked chip, and wherein
said master integrated circuit die and said at least one slave integrated circuit die are cut from a wafer which is diced to provide master and slave integrated circuit dies, each master and slave integrated circuit die having master and slave elements which are used for only one kind of individual integrated circuit die which is cut from a wafer having said single image, and which master and slave elements are located along die edges and at die centers before dicing separation of individual integrated circuit dies from said wafer, the location of said master and slave elements determining that said master integrated circuit die is used as a master die and not as a slave element in said 3D integrated structure when a master dicing pattern has cut out the master integrated circuit die from said wafer, and the location of said master and slave elements determining that said slave integrated circuit die is used as a slave integrated circuit die when a slave dicing pattern has cut out the slave integrated circuit die from said wafer.

9. The three dimensional circuit stack for an electronic system according to claim 8, wherein a slave integrated circuit die cut from a wafer has through silicon vias (TSVs) slave elements formed thereon and determine that said slave integrated circuit die is used as a slave die and not as a master die when a dicing pattern has cut out the slave integrated circuit die from said wafer and locates said through silicon vias (TSV) slave elements of said slave integrated circuit die for connection of circuits on said slave integrated circuit die to other chip elements.

10. The three dimensional circuit stack for an electronic system according to claim 9, wherein said master integrated circuit die cut from a wafer has through I/O logic driver master elements formed thereon and which determine that said master integrated circuit die is used as a master die and not as a slayer die when a dicing pattern has cut out the master integrated circuit die from said wafer and locates said I/O logic driver master elements for connection of circuits on said master integrated circuit die and enables connection to other chips external to said three dimensional circuit stack via bonding to a board/asic substrate carrying a master bus.

11. The integrated circuit chip element according to claim 8, wherein I/O kerfs and slave kerfs are located on the said master integrated circuit die and said slave integrated circuit die, and determine by their position in a dicing cut the function of the integrated circuit die after it has been cut, the I/O kerfs and slave kerfs having an orthogonal pattern so that a dicing cut along an I/O kerf cut pattern causes I/O drivers to cross in a centered master integrated circuit die after separation and slave kerfs will locate Through Silicon Vias crossing in a centered slave integrated circuit die after separation.

12. The integrated circuit chip element according to claim 11, wherein said I/O kerfs and slave kerfs are located with an orthogonal pattern for each kerf pattern crossing with a shift ½ way across a die which has been be separated from the wafer so as to provide an I/O interconnection pattern for a master integrated circuit die and a second interconnection TSV region crossing kerf pattern, said kerf patterns establishing the function of an integrated circuit die cut from a wafer by being shifted ½ way across an integrated circuit die.

13. The integrated circuit chip element according to claim 8 wherein the master and one or more slave integrated circuit dies separated from wafers having a common image are stacked in a 3D circuit stack with interconnecting Through Silicon Vias crossing the center of a die along a kerf pattern which has not been cut is used to interconnect the dies of said stacked 3D circuit structure and to interconnect the slave integrated circuit dies to a master integrated circuit die element of said integrated 3D circuit stack structure, and wherein I/O logic connecting said master die to a master bus on a board/asic substrate as the only die of the integrated circuit stack coupled externally of the integrated circuit stack crosses the center of said master integrated circuit die along a kerf pattern which has not been cut.

14. The integrated circuit chip element according to claim 85 wherein in the process of manufacturing master and slave integrated circuit dies which are cut from a wafer and before said dies are separated from a wafer, a plurality of wafers are stacked and vertically aligned as stacked master slave wafers, said wafers being aligned with one of said vertically aligned wafers being shifted with an aligned kerf pattern crossing shifted ½ way across the die pattern before it is cut, such that a cut along a kerf line will separate master dies from one of said vertically aligned wafers and slave dies adjacent to said master dies by cutting through aligned I/O kerf patterns of one wafer and TSV kerf patterns of a different wafer of said stacked wafers to provide a resulting stack of vertically aligned chips having aligned I/O interconnection patterns and TSV patterns of respective master die and slave dies.

15. A method for integrated circuit fabrication, comprising:
creating a single wafer with a wafer image of integrated circuits which have die circuit connection elements useful as master and as slave elements in dies separable from said single wafer,
and separating individual integrated circuit dies from said single wafer as chip dies having elements for interconnection of the separated individual integrated circuit dies with master and slave elements which are used for only one kind of separated individual integrated circuit dies which are located along die edges and at die centers before dicing separation of individual integrated circuit chips, the location of said master and slave elements determining whether said separated individual integrated circuit chip is used as a master or a slave element in a stacked circuit configuration.

16. The method according to claim 15, wherein the step of separating individual circuit dies locates master elements at die centers of a master die having logic master elements for connection to a master bus, and locates through silicon vias (TSV) slave elements of a die cut from a like wafer with the same wafer image of integrated circuits used as a slave die so that said slave die is connected to a die having logic master elements for coupling to a master bus in a stacked circuit configuration.

17. The method according to claim 16, wherein after separation individual circuit dies are stacked as a 3D chip stack bump bonded board/asic substrate carrying said master bus, each die of said 3D chip stack being separated from a single wafer with a common wafer image of integrated circuits which have die circuit connection elements useful as master and as slave elements in dies separable from one or more wafers having said common wafer image.

18. The method according to claim 16, wherein in creating a single wafer with a wafer image of integrated circuits which have die circuit connection elements useful as master and as slave elements in dies separable from said single wafer, I/O kerfs and slave kerfs are located for said wafer image with a orthogonal pattern so that a dicing cut along an I/O kerf will cause I/O drivers to cross in a centered master die after separation and slave kerfs will locate Through Silicon Vias crossing in a centered slave die after separation.

19. The method according to claim 18, wherein said I/O kerfs and slave kerfs are located for said wafer image with an orthogonal pattern for each kerf pattern crossing with a shift ½ way across a die which would be separated from the wafer so as to provide an I/O interconnection pattern with one cut which when cut allows a chip cut to be a master die and a second interconnection TSV region crossing kerf pattern with a second cut shifted ½ way across the die which when cut allows the chip cut to be a slave die.

20. The method according to claim 19 wherein after separating dies from wafers having a common single image, a plurality of slave dies are stacked in a 3D circuit stack with interconnecting Through Silicon Vias crossing the center being used to interconnect the plurality of slave dies and to connect the plurality of stacked slave dies placed on a master die to a master die as an integrated 3D circuit stack, and connecting said master die to a master bus on a board/asic substrate as the only die of the integrated circuit stack coupled externally of the integrated circuit stack.

21. The method according to claim 20 wherein before said dies are separated from a wafer, a plurality of wafers are stacked and vertically aligned as stacked master slave wafers, said wafers being aligned with one of said vertically aligned wafers being shifted with an aligned kerf pattern crossing shifted ½ way across the die pattern before it is cut, such that a cut along a kerf line will separate master dies from one of said vertically aligned wafers and slave dies adjacent to said master dies by cutting through aligned I/O kerf patterns of one wafer and TSV kerf patterns of a different wafer of said stacked wafers to provide a resulting stack of vertically aligned chips having aligned I/O interconnection patterns and TSV patterns of respective master die and slave dies.
